(19) United States
(12) Patent Application Publication
(10) Pub. No.: US 2025/0357291 A1
(43) Pub. Date: Nov. 20, 2025

(54) BOARD-LEVEL SEMICONDUCTOR PACKAGE

(71) Applicant: SAMSUNG ELECTRONICS CO., LTD., Suwon-si (KR)

(72) Inventors: Junho LEE, Suwon-si (KR); Insik HAN, Suwon-si (KR)

(73) Assignee: SAMSUNG ELECTRONICS CO., LTD., Suwon-si (KR)

(21) Appl. No.: 19/026,920

(22) Filed: Jan. 17, 2025

(30) Foreign Application Priority Data
May 16, 2024 (KR) 10-2024-0064137

(51) Int. Cl. H01L 23/498; H01L 21/48; H01L 23/00

(52) U.S. Cl. CPC H01L 23/49816; H01L 21/4853; H01L 23/49833; H01L 23/562

(57) ABSTRACT

Provided is a board-level semiconductor package including: board pads that are separate from one another; a package substrate including substrate pads that are separate from one another and face the board pads; and connection balls between the board pads and the package substrate, wherein the connection balls connect the board pads to the substrate pads, wherein the connection balls include: metal core solder balls; and core-free solder balls, wherein the substrate pads include first and second substrate pads, and wherein the metal core solder balls are on the first substrate pads, the core-free solder balls are on the second substrate pads, and a diameter of a first second substrate pad among the second substrate pads is different a diameter of a second substrate pad from among the second substrate pads.

### CROSS-REFERENCE TO RELATED APPLICATION

This application is based on and claims priority to Korean Patent Application No. 10-2024-0064137, filed on May 16, 2024, in the Korean Intellectual Property Office, the disclosure of which is incorporated by reference herein in its entirety.

### BACKGROUND

### 1. Field

The disclosure relates to a semiconductor package, and more particularly, to a board-level semiconductor package.

### 2. Description of Related Art

Along with the miniaturization of electronic devices, semiconductor packages have become gradually smaller, thinner, and lighter. In addition, as the functions of electronic devices become more complicated, a modular semiconductor package having a plurality of semiconductor packages mounted on a package substrate is frequently used. Accordingly, due to thermal and mechanical stress applied to a package substrate included in a semiconductor package or a modular semiconductor package, there occurs warpage that bends the package substrate.

### SUMMARY

Provided is a board-level semiconductor package capable of electrically connecting a semiconductor package or a modular semiconductor package including a package substrate with warpage to board pads or a board substrate.

According to an aspect of the disclosure, a board-level semiconductor package includes: a plurality of board pads, wherein the plurality of board pads are separate from one another; a package substrate including a plurality of substrate pads, wherein the plurality of substrate pads are separate from one another and respectively face the plurality of board pads; and a plurality of connection balls between the plurality of board pads and the package substrate, wherein the plurality of connection balls connect the plurality of board pads to the plurality of substrate pads, wherein the plurality of connection balls include: a plurality of metal core solder balls; and a plurality of core-free solder balls, wherein the plurality of substrate pads include first substrate pads and second substrate pads, wherein the plurality of metal core solder balls are on the first substrate pads, and the plurality of core-free solder balls are on the second substrate pads, and wherein a diameter of a first second substrate pad among the second substrate pads is different a diameter of a second substrate pad from among the second substrate pads.

According to an aspect of the disclosure, a board-level semiconductor package includes: a plurality of board pads, wherein the plurality of board pads are separate from one another; a package substrate including a plurality of substrate pads, wherein the plurality of substrate pads are separate from one another and respectively face the plurality of board pads; and a plurality of connection balls between the plurality of board pads and the package substrate, wherein the plurality of connection balls connect the plurality of board pads to the plurality of substrate pads, wherein the plurality of connection balls include: a plurality of metal core solder balls; and a plurality of core-free solder balls, wherein the plurality of substrate pads include first substrate pads and second substrate pads, wherein the plurality of metal core solder balls are on the first substrate pads, and the plurality of core-free solder balls are one the second substrate pads, wherein the first substrate pads and the plurality of metal core solder balls are on an edge portion of the package substrate, and wherein diameters of the second substrate pads decrease from the edge portion to a center portion of the package substrate.

According to an aspect of the disclosure, a board-level semiconductor package includes: a plurality of board pads, wherein the plurality of board pads are separate from one another; a package substrate including a plurality of substrate pads, wherein the plurality of substrate pads are separate from one another and respectively face the plurality of board pads; and a plurality of connection balls between the plurality of board pads and the package substrate, wherein the plurality of connection balls connect the plurality of board pads to the plurality of substrate pads, wherein the plurality of connection balls include: a plurality of metal core solder balls; and a plurality of core-free solder balls, wherein the plurality of substrate pads include first substrate pads and second substrate pads, wherein the plurality of metal core solder balls are on the first substrate pads, and the plurality of core-free solder balls are on the second substrate pads, wherein the first substrate pads and the plurality of metal core solder balls are on a center portion of the package substrate, and wherein diameters of the second substrate pads decrease from the center portion to an edge portion of the package substrate.

### BRIEF DESCRIPTION OF DRAWINGS

The above and other aspects and features of certain embodiments of the present disclosure will be more apparent from the following description taken in conjunction with the accompanying drawings, in which:

FIG. 1 is a cross-sectional view illustrating a board-level semiconductor package according to one or more embodiments;

FIG. 2 is a cross-sectional view illustrating coupling of a board substrate and a modular semiconductor package of FIG. 1;

FIG. 3 is a top view of the modular semiconductor package of FIG. 1;

FIG. 4 is a partial magnified cross-sectional view of the board-level semiconductor package of FIG. 1;

FIG. 5 is a magnified cross-sectional view of a metal core solder ball usable for the board-level semiconductor package of FIG. 1;

FIG. 6 is a planar layout diagram illustrating connection balls on substrate pads of a package substrate of FIGS. 1 and 4;

FIG. 7 is a partial magnified planar layout diagram of FIG. 6;

FIGS. 8A, 8B, 8C and 8D are perspective views illustrating a process of forming metal core solder balls on first substrate pads of the package substrate of FIGS. 6 and 7;

FIGS. 9A, 9B and 9C are perspective views illustrating a process of forming core-free solder balls on second substrate pads of the package substrate of FIGS. 6 and 7;

FIG. 10 is a planar layout diagram illustrating connection balls on substrate pads of a package substrate according to one or more embodiments;

FIG. 11 is a cross-sectional view illustrating a board-level semiconductor package according to one or more embodiments;

FIG. 12 is a partial magnified cross-sectional view of the board-level semiconductor package of FIG. 11;

FIG. 13 is a planar layout diagram illustrating connection balls on substrate pads of a package substrate of FIGS. 11 and 12;

FIG. 14 is a partial magnified planar layout diagram of FIG. 13;

FIG. 15 is a planar layout diagram illustrating connection balls on substrate pads of a package substrate according to one or more embodiments; and

FIG. 16 is a block diagram schematically illustrating a board-level semiconductor package according to one or more embodiments.

### DETAILED DESCRIPTION

Hereinafter, embodiments are described in detail with reference to the accompanying drawings. The embodiments below may be implemented alone or in combination, and the disclosure is not limit to the embodiments described here.

In the following description, like reference numerals refer to like elements throughout the specification.

As used herein, a plurality of “units”, “modules”, “members”, and “blocks” may be implemented as a single component, or a single “unit”, “module”, “member”, and “block” may include a plurality of components. More generally, a component expressed in the singular may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

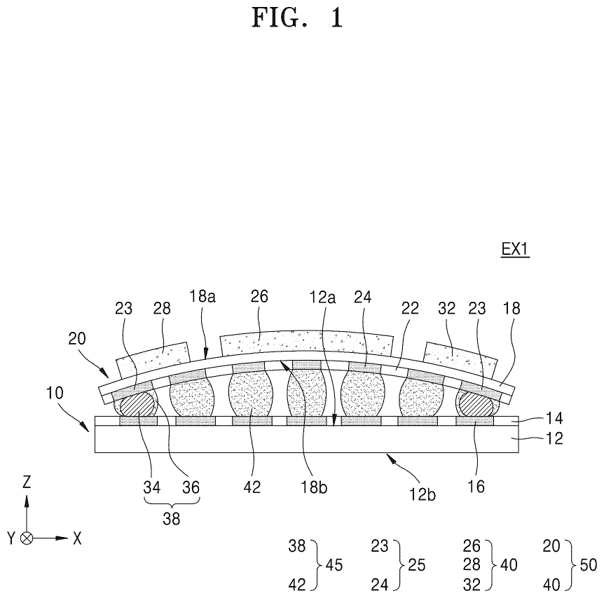

FIG. 1 is a cross-sectional view illustrating a board-level semiconductor package EX1 according to one or more embodiments.

Particularly, the board-level semiconductor package EX1 may include a board substrate 10, a modular semiconductor package 50 including a package substrate 20 and semiconductor packages 40, and connection balls 45. In the drawings below, an X-direction indicates a first horizontal direction parallel to the board substrate 10, and a Y-direction indicates a second horizontal direction parallel to the board substrate 10 and perpendicular to the X-direction. A Z-direction may be a vertical direction perpendicular to the board substrate 10.

The board substrate 10 may include a board body 12 having an upper surface 12a and a lower surface 12b, a plurality of board pads 16 on the upper surface 12a of the board body 12 and separated from each other, and a board protective layer 14 isolating the plurality of board pads 16.

The board body 12 may include at least one of a prepreg resin, a thermosetting epoxy resin, a thermoplastic epoxy resin, or a filler-containing resin. The board substrate 10 may indicate the board body 12 in a narrow meaning. The board substrate 10 may be referred to as a motherboard. The board substrate 10 may be a printed circuit board.

The plurality of board pads 16 may be on the upper surface 12a of the board body 12 and separated from each other in the X-direction and the Y-direction. Each of the plurality of board pads 16 may be a single layer of a metal, such as tin (Sn), silver (Ag), or copper (Cu), or multiple layers thereof. The board protective layer 14 may be on the upper surface 12a of the board body 12 in a region except for the plurality of board pads 16. The board protective layer 14 may be a solder resist layer.

The package substrate 20 may include a package body 18 having an upper surface 18a and a lower surface 18b, a plurality of substrate pads 25 on the lower surface 18b of the package body 18 and separated from each other, and a substrate protective layer 22 isolating the plurality of substrate pads 25.

The package body 18 may include at least one of a prepreg resin, a thermosetting epoxy resin, a thermoplastic epoxy resin, or a filler-containing resin. The package substrate 20 may indicate the package body 18 in a narrow meaning. The package substrate 20 may be a printed circuit board.

The package substrate 20 may have warped during a manufacturing process thereof. In one or more embodiments, the package substrate 20, i.e., the package body 18, may have positive warpage protruding upward (e.g., may be concave upward), away from the board substrate 10. The plurality of substrate pads 25 may be on the lower surface 18b of the package body 18 and separated from each other in the X-direction and the Y-direction.

Each of the plurality of substrate pads 25 may be a single layer of a metal, such as Sn, Ag, or Cu, or multiple layers thereof. The substrate protective layer 22 may be on the lower surface 18b of the package body 18 in a region except for the plurality of substrate pads 25. The substrate protective layer 22 may be a solder resist layer.

The semiconductor packages 40 are on the upper surface 18a of the package substrate 20, i.e., the package body 18, and separated from each other. The semiconductor packages 40 may include, for example, a memory semiconductor package and a non-memory semiconductor package. The semiconductor packages 40 may include a first semiconductor package 26, a second semiconductor package 28, and a third semiconductor package 32 in a cross-sectional view. Although the semiconductor packages 40 include three semiconductor packages in the cross-sectional view of the present embodiment, only at least one semiconductor package may be provided.

A structure including the package substrate 20 and the semiconductor packages 40 on the package substrate 20 may be referred to as the modular semiconductor package 50. In the present embodiment, the semiconductor packages 40 are on the package substrate 20, but semiconductor chips may be on the package substrate 20.

The connection balls 45 may be between the board substrate 10 and the package substrate 20 to electrically connect the plurality of board pads 16 to the plurality of substrate pads 25, respectively. The connection balls 45 may include a plurality of metal core solder balls 38 and a plurality of core-free solder balls 42.

Each of the plurality of metal core solder balls 38 may include a metal core 34 and a core solder layer 36 wrapping the metal core 34. The metal core 34 may include Cu, and the core solder layer 36 may include a solder composition including Sn as a base metal and Ag, Cu, bismuth (Bi), or nickel (Ni) as an auxiliary metal.

The plurality of core-free solder balls 42 may indicate solder balls without a metal core. The plurality of core-free solder balls 42 may include the same material as the core solder layer 36. The plurality of metal core solder balls 38 and the plurality of core-free solder balls 42 may be on the plurality of substrate pads 25 to electrically connect the plurality of board pads 16 to the plurality of substrate pads 25, respectively. The solidity of the plurality of metal core solder balls 38 may be greater than the solidity of the plurality of core-free solder balls 42.

The plurality of substrate pads 25 may be classified into first substrate pads 23, on which the plurality of metal core solder balls 38 are respectively disposed, and second substrate pads 24, on which the plurality of core-free solder balls 42 are respectively disposed. As described above, the package substrate 20 may have warped during a manufacturing process thereof.

For example, as described above, the package substrate 20, i.e., the package body 18, may have positive warpage protruding upward (e.g., may be concave upward), away from the board substrate 10. Accordingly, the plurality of metal core solder balls 38 are on an edge portion of the package substrate 20.

In addition, the diameters of the second substrate pads 24, on which the plurality of core-free solder balls 42 are respectively disposed, gradually decrease from the edge portion to a center portion of the package substrate 20. In one or more embodiments, the diameter of each of the second substrate pads 24, on which the plurality of core-free solder balls 42 are respectively disposed, may be about 50% to about 100% of the diameter of each of the first substrate pads 23, on which the plurality of metal core solder balls 38 are respectively disposed. The heights of the plurality of core-free solder balls 42 respectively on the second substrate pads 24 may gradually increase from the edge portion to the center portion of the package substrate 20.

The board-level semiconductor package EX1 according to the disclosure may be configured such that the diameters of the second substrate pads 24, on which the plurality of core-free solder balls 42 are respectively disposed, vary according to the degree and direction of the warpage of the package substrate 20. In addition, the heights of the plurality of core-free solder balls 42 respectively on the second substrate pads 24 may vary according to the degree and direction of the warpage of the package substrate 20.

In addition, the board-level semiconductor package EX1 according to the disclosure may include the board substrate 10 and the package substrate 20 electrically connected to each other using the plurality of metal core solder balls 38 and the plurality of core-free solder balls 42 and have improved package flatness. In other words, in the board-level semiconductor package EX1 according to the disclosure, the package flatness of the board substrate 10 and the package substrate 20 may be improved using the plurality of metal core solder balls 38, and the board substrate 10 may be electrically connected to the package substrate 20 by using the plurality of core-free solder balls 42.

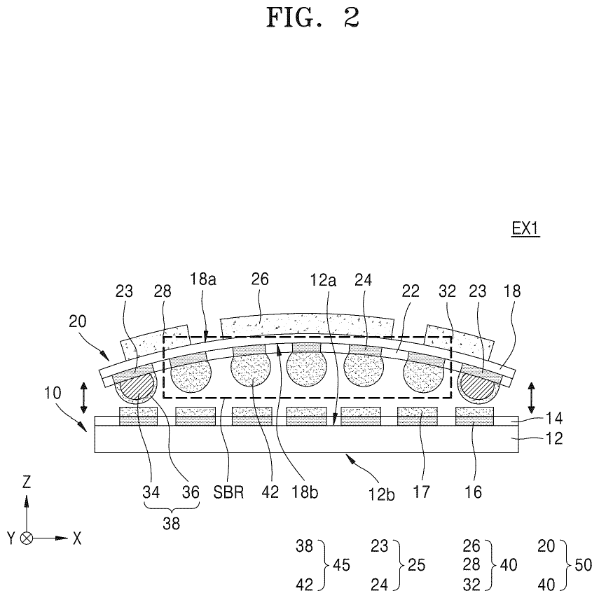

FIG. 2 is a cross-sectional view illustrating coupling of the board substrate 10 and the modular semiconductor package 50 of FIG. 1.

Particularly, in FIG. 2, like reference numerals of FIG. 1 denote like members. In FIG. 2, the description made with reference to FIG. 1 is simply repeated or omitted. In the board-level semiconductor package EX1, the board substrate 10 may be coupled to the modular semiconductor package 50 including the semiconductor packages 40 mounted on the package substrate 20 by using the connection balls 45.

In the board-level semiconductor package EX1, the modular semiconductor package 50 having the connection balls 45 formed on the lower surface thereof is coupled onto the board substrate 10 by using a solder paste 17 to bring the connection balls 45 into close contact with the plurality of board pads 16 of the board substrate 10.

More particularly, the board substrate 10 may include the board body 12 having the upper surface 12a and the lower surface 12b, the plurality of board pads 16 on the upper surface 12a of the board body 12 and separated from each other, and the board protective layer 14 isolating the plurality of board pads 16.

The package substrate 20 may include the package body 18 having the upper surface 18a and the lower surface 18b, the plurality of substrate pads 25 on the lower surface 18b of the package body 18 and separated from each other, and the substrate protective layer 22 isolating the plurality of substrate pads 25. The connection balls 45 may be respectively on the plurality of substrate pads 25 on the lower surface 18b of the package body 18.

The connection balls 45 may include the plurality of metal core solder balls 38 and the plurality of core-free solder balls 42. The plurality of substrate pads 25 may be classified into the first substrate pads 23, on which the plurality of metal core solder balls 38 are respectively disposed, and the second substrate pads 24, on which the plurality of core-free solder balls 42 are respectively disposed.

The semiconductor packages 40 may be on the upper surface 18a of the package body 18 and separated from each other. The connection balls 45 may include the plurality of metal core solder balls 38 and the plurality of core-free solder balls 42. The package substrate 20, i.e., the package body 18, may have positive warpage protruding upward (e.g., may be concave upward), away from the board substrate 10.

Because the package substrate 20 has positive warpage protruding upward (e.g., is concave upward), away from the board substrate 10, the gap between an edge portion of the package substrate 20 and an edge portion of the board substrate 10 may be small, and the gap between a center portion SBR of the package substrate 20 and a center portion of the board substrate 10 may be large. Accordingly, the plurality of metal core solder balls 38 may be on the edge portion of the package substrate 20 to suppress the occurrence of a bridge between neighboring solder balls 42 and improve package flatness even when the gap between the package substrate 20 and the board substrate 10 is small.

The plurality of core-free solder balls 42 may be on the center portion SBR of the package substrate 20. The plurality of core-free solder balls 42 may be on the center portion SBR of the package substrate 20. The diameter of each of the second substrate pads 24, on which the plurality of core-free solder balls 42 are respectively disposed, may be about 50% to about 100% of the diameter of each of the first substrate pads 23, on which the plurality of metal core solder balls 38 are respectively disposed.

The diameters of the second substrate pads 24, on which the plurality of core-free solder balls 42 are respectively disposed, may gradually decrease from the edge portion to the center portion SBR of the package substrate 20 and the heights of the plurality of core-free solder balls 42 respectively on the second substrate pads 24 may gradually increase from the edge portion to the center portion SBR of the package substrate 20.

Accordingly, the package substrate 20 may be connected to the board substrate 10 by using the plurality of core-free solder balls 42 on the center portion SBR of the package substrate 20 even when the gap between the package substrate 20 and the board substrate 10 is large.

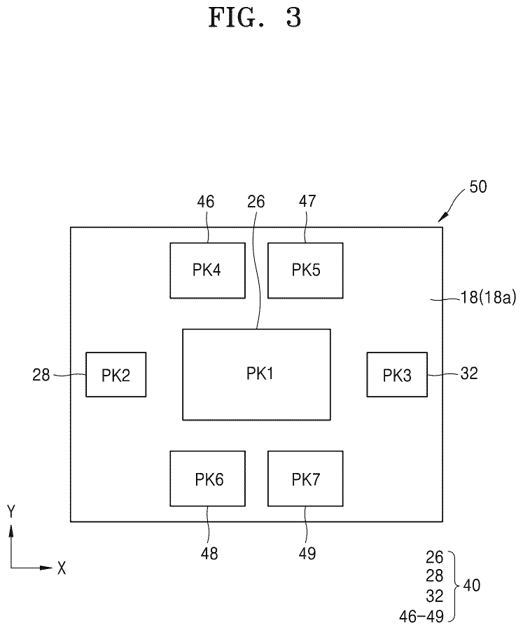

FIG. 3 is a top view of the modular semiconductor package 50 of FIG. 1.

Particularly, the modular semiconductor package 50 may include semiconductor packages 40 on the upper surface 18a of the package body 18 constituting the package substrate 20 (see FIG. 1).

The semiconductor packages 40 may include a first semiconductor package 26, a second semiconductor package 28, a third semiconductor package 32, a fourth semiconductor package 46, a fifth semiconductor package 47, a sixth semiconductor package 48, and a seventh semiconductor package 49 in a plan view.

The first semiconductor package 26 may be on a center portion of the package body 18 constituting the package substrate 20 (see FIG. 1) and the second to seventh semiconductor packages 28, 32, 46, 47, 48, and 49 may be on an edge portion of the package body 18 constituting the package substrate 20 (see FIG. 1).

In one or more embodiments, the first semiconductor package 26 may have a larger size than each of the second to seventh semiconductor packages 28, 32, 46, 47, 48, and 49. The second to seventh semiconductor packages 28, 32, 46, 47, 48, and 49 may have different sizes.

Because the first to seventh semiconductor packages 26, 28, 32, 46, 47, 48, and 49 have different sizes, when the modular semiconductor package 50 is manufactured, different pressure may be applied to each region of the package body 18 constituting the package substrate 20 (see FIG. 1), thereby resulting in warpage of package substrate 20.

In addition, in one or more embodiments, a heat sink of a metal member may be arranged on each of the first to seventh semiconductor packages 26, 28, 32, 46, 47, 48, and 49. Accordingly, when the modular semiconductor package 50 is manufactured, different pressure may be applied to each region of the package body 18 constituting the package substrate 20 (see FIG. 1) due to the heat sinks, thereby resulting in warpage of package substrate 20.

Although the semiconductor packages 40 include seven semiconductor packages in the top view of the present embodiment, only at least one semiconductor package may be provided.

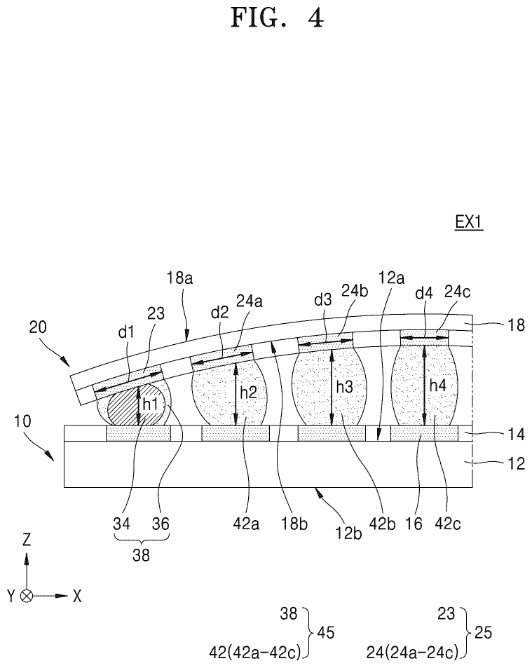

FIG. 4 is a partial magnified cross-sectional view of the board-level semiconductor package EX1 of FIG. 1.

Particularly, in FIG. 4, like reference numerals of FIG. 1 denote like members. In FIG. 4, the description made with reference to FIG. 1 is simply repeated or omitted. The board-level semiconductor package EX1 may include the board substrate 10, the package substrate 20, and connection balls 45.

The board substrate 10 may include the board body 12 having the upper surface 12a and the lower surface 12b, board pads 16, and the board protective layer 14. The package substrate 20 may include the package body 18 having the upper surface 18a and the lower surface 18b, substrate pads 25, and the substrate protective layer 22. The connection balls 45 may be respectively on the substrate pads 25 on the lower surface 18b of the package body 18.

The connection balls 45 may include a metal core solder ball 38 and core-free solder balls 42. The heights of the core-free solder balls 42 respectively on second substrate pads 24 may differ on an edge portion and a center portion of the package substrate 20. The core-free solder balls 42 may include a first sub-core-free solder ball 42a, a second sub-core-free solder ball 42b, and a third sub-core-free solder ball 42c.

The first sub-core-free solder ball 42a, the second sub-core-free solder ball 42b, and the third sub-core-free solder ball 42c may have heights of h2, h3, and h4, respectively. The metal core solder ball 38 may have a height of h1. In one or more embodiments, the height h1 of the metal core solder ball 38 may be several um to hundreds of μm.

The substrate pads 25 may include a first substrate pad 23, on which the metal core solder ball 38 is disposed, and the second substrate pads 24, on which the core-free solder balls 42 are respectively disposed. The diameter of the first substrate pad 23 may be d1. In one or more embodiments, the diameter d1 of the first substrate pad 23 may be several μm to hundreds of μm.

The diameters of the second substrate pads 24 may be d2, d3, and d4. In one or more embodiments, the diameters d2, d3, and d4 of the second substrate pads 24 may be several um to hundreds of μm. In one or more embodiments, each of the diameters d2, d3, and d4 of the second substrate pads 24 may be about 50% to about 100% of the diameter d1 of the first substrate pad 23.

The second substrate pads 24 may include a first sub-substrate pad 24a, a second sub-substrate pad 24b, and a third sub-substrate pad 24c. The first sub-substrate pad 24a, the second sub-substrate pad 24b, and the third sub-substrate pad 24c may have diameters of d2, d3, and d4, respectively.

The metal core solder ball 38 may connect a board pad 16 to the first substrate pad 23. The first sub-core-free solder ball 42a may connect a board pad 16 to the first sub-substrate pad 24a. The second sub-core-free solder ball 42b may connect a board pad 16 to the second sub-substrate pad 24b. The third sub-core-free solder ball 42c may connect a board pad 16 to the third sub-substrate pad 24c.

As described above, the package substrate 20 of the board-level semiconductor package EX1 may have positive warpage protruding upward (e.g., may be concave upward), away from the board substrate 10. As a result, the gap between the edge portion of the package substrate 20 and an edge portion of the board substrate 10 may be small and the gap between the center portion of the package substrate 20 and a center portion of the board substrate 10 may be large.

Accordingly, the diameters of the second substrate pads 24, on which the core-free solder balls 42 are respectively disposed, may gradually decrease from the edge portion to the center portion of the package substrate 20. The diameters of the first sub-substrate pad 24a, the second sub-substrate pad 24b, and the third sub-substrate pad 24c may decrease in the order of d2, d3, and d4. In one or more embodiments, the diameter d1 of the first substrate pad 23 may be greater than the diameter d2 of the first sub-substrate pad 24a.

In addition, the heights of the core-free solder balls 42 respectively on the second substrate pads 24 may gradually increase from the edge portion to the center portion of the package substrate 20. That is, the heights of the first sub-core-free solder ball 42a, the second sub-core-free solder ball 42b, and the third sub-core-free solder ball 42c may increase in the order of h2, h3, and h4.

In one or more embodiments, the heights h2, h3, and h4 of the core-free solder balls 42, i.e., the first to third sub-core-free solder balls 42a, 42b, and 42c, may be several μm to hundreds of μm. In one or more embodiments, the height h1 of the metal core solder ball 38 may be less than the height h2 of the first sub-core-free solder ball 42a.

Accordingly, the package substrate 20 may be connected to the board substrate 10 by using the metal core solder ball 38 even when the gap between the package substrate 20 and the board substrate 10 is small at the edge portion of the package substrate 20. In addition, the package substrate 20 may be connected to the board substrate 10 by using the first to third sub-core-free solder balls 42a, 42b, and 42c even when the gap between the package substrate 20 and the board substrate 10 is large at the center portion of the package substrate 20.

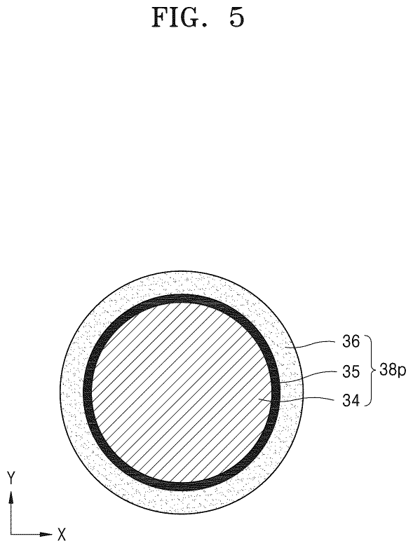

FIG. 5 is a magnified cross-sectional view of a metal core solder ball usable for the board-level semiconductor package EX1 of FIG. 1.

Particularly, as described above, the board-level semiconductor package EX1 of FIG. 1 may use the metal core solder ball 38 including the metal core 34 and the core solder layer 36 wrapping the metal core 34.

In one or more embodiments, the board-level semiconductor package EX1 of FIG. 1 may use a metal core solder ball 38p including the metal core 34, an interface layer 35 wrapping the metal core 34, and the core solder layer 36 wrapping the interface layer 35. The interface layer 35 may be a material layer for making easy coupling between the metal core 34 and the core solder layer 36. In one or more embodiments, the interface layer 35 may be a Ni layer.

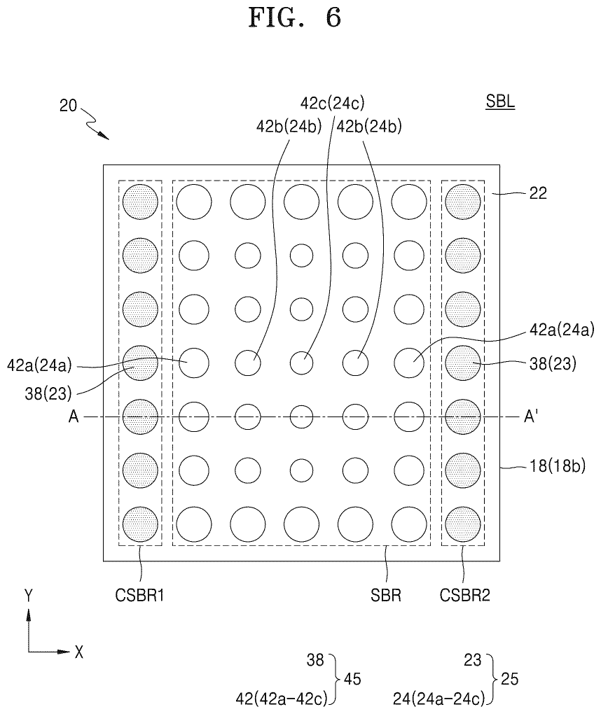

FIG. 6 is a planar layout diagram SBL illustrating connection balls on substrate pads of the package substrate 20 of FIGS. 1 and 4, and FIG. 7 is a partial magnified planar layout diagram of FIG. 6.

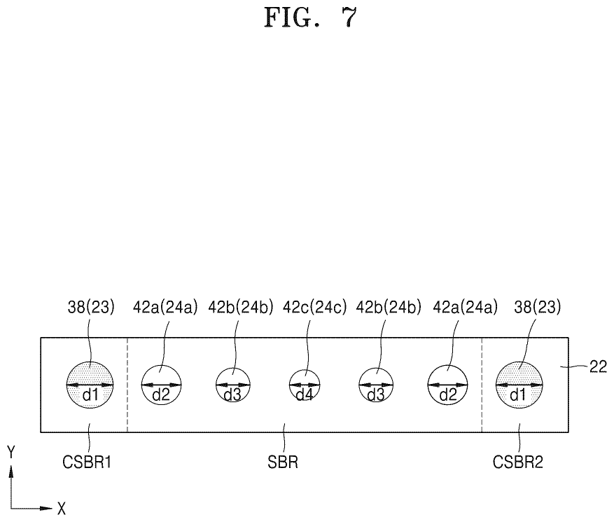

Particularly, in FIGS. 6 and 7, like reference numerals of FIGS. 1 and 4 denote like members. In FIGS. 6 and 7, the description made with reference to FIGS. 1 and 4 is simply repeated or omitted. The planar layout diagram SBL of FIG. 6 shows connection balls 45 on the lower surface 18b of the package body 18 constituting the package substrate 20. FIG. 7 may be a cross-sectional view taken along line A-A′ of FIG. 6.

The package substrate 20, i.e., the package body 18, may have a quadrangular shape. The connection balls 45 may be respectively on substrate pads 25 on the lower surface 18b of the package body 18. The substrate protective layer 22 isolating the substrate pads 25 may be on the lower surface 18b of the package body 18.

The substrate pads 25 may include first substrate pads 23 and second substrate pads 24. The connection balls 45 may include metal core solder balls 38 and core-free solder balls 42. The metal core solder balls 38 may be respectively on the first substrate pads 23. The core-free solder balls 42 may be respectively on the second substrate pads 24.

The metal core solder balls 38 may be on edge portions, e.g., first and second edge portions CSBR1 and CSBR2, of the package substrate 20, i.e., the package body 18. The metal core solder balls 38 may be on the first edge portion CSBR1 and the second edge portion CSBR2 near the edges of two sides of the quadrangular-shaped package substrate 20.

In one or more embodiments, the metal core solder balls 38 may be on only any one of the first edge portion CSBR1 and the second edge portion CSBR2. In one or more embodiments, all the metal core solder balls 38 of FIG. 6 are near the edges of two sides of the package substrate 20 and not near the other edges.

The core-free solder balls 42 may be on a center portion SBR of the package substrate 20, i.e., the package body 18. The core-free solder balls 42 may be at an inner side of the first edge portion CSBR1 and the second edge portion CSBR2 of the quadrangular-shaped package substrate 20.

The diameters of the second substrate pads 24, on which the core-free solder balls 42 are respectively disposed, may vary on the center portion SBR of the package substrate 20. For example, the diameters of the second substrate pads 24, on which the core-free solder balls 42 are respectively disposed, may gradually decrease from the first and second edge portions CSBR1 and CSBR2 to the center portion SBR.

The diameters of the first sub-substrate pad 24a, the second sub-substrate pad 24b, and the third sub-substrate pad 24c constituting the second substrate pads 24 may decrease in the order of d2, d3, and d4. In one or more embodiments, the diameter d1 of the first substrate pad 23 may be greater than the diameter d2 of the first sub-substrate pad 24a.

As described above with reference to FIG. 4, the heights of the core-free solder balls 42 respectively on the second substrate pads 24 may vary on the center portion SBR of the package substrate 20. The heights of the core-free solder balls 42 respectively on the second substrate pads 24 may gradually increase from the first and second edge portions SBR1 and SBR2 to the center portion SBR of the package substrate 20.

For example, as described above with reference to FIG. 4, the heights of the first sub-core-free solder ball 42a, the second sub-core-free solder ball 42b, and the third sub-core-free solder ball 42c may increase in the order of h2, h3, and h4. In one or more embodiments, the height h1 of the metal core solder ball 38 may be less than the height h2 of the first sub-core-free solder ball 42a.

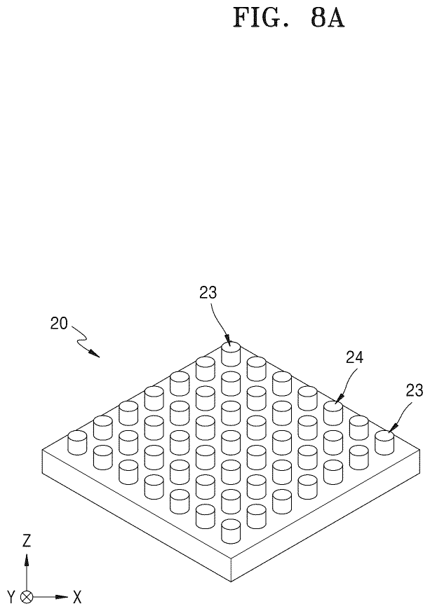

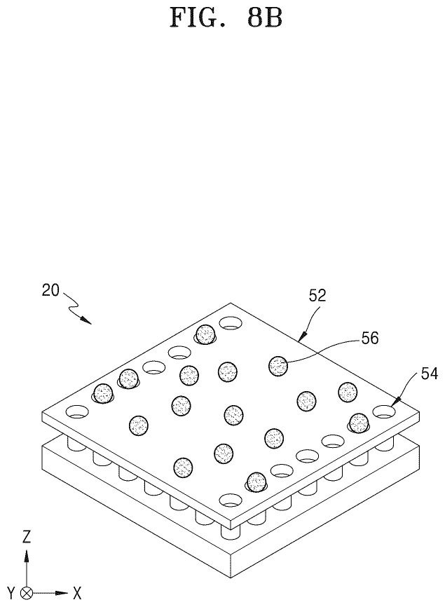

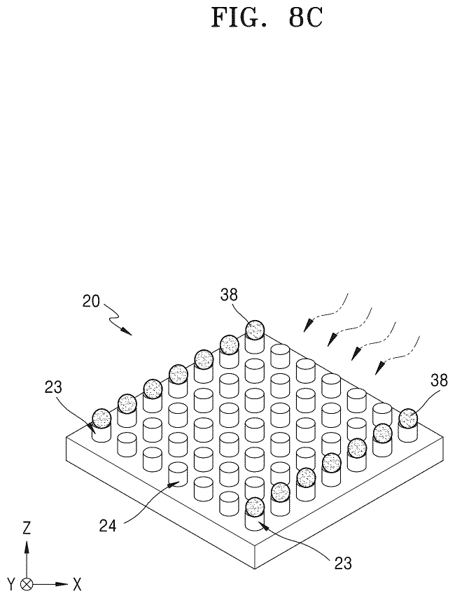

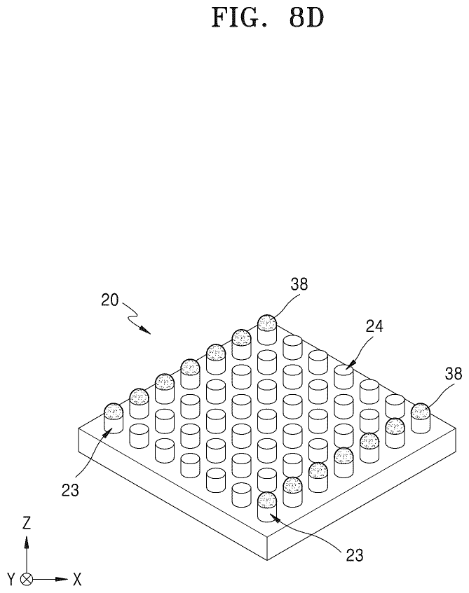

FIGS. 8A to 8D are perspective views illustrating a process of forming the metal core solder balls 38 on the first substrate pads 23 of the package substrate 20 of FIGS. 6 and 7.

As shown in FIG. 8A, the first substrate pads 23 and the second substrate pads 24 are formed on the package substrate 20. The first substrate pads 23 and the second substrate pads 24 are separated from each other in a first direction (the X-direction) and a second direction (the Y-direction).

The first substrate pads 23 may be on an edge portion of the package substrate 20 and the second substrate pads 24 may be on a center portion of the package substrate 20. Although FIG. 8A shows for convenience that the diameters of the second substrate pads 24 are identical to each other, as described above, the diameters of the second substrate pads 24 may be adjusted to vary according to the degree and direction of the warpage of the package substrate 20.

As shown in FIG. 8B, a solder mask 52 having openings 54 is disposed on the package substrate 20. The openings 54 in the solder mask 52 may be formed to correspond to the first substrate pads 23. The solder mask 52 is coated or applied with a metal core solder material 56.

Referring to FIG. 8C, the metal core solder balls 38 may be respectively formed on the first substrate pads 23 by passing the metal core solder material 56 through the openings 54 formed in the solder mask 52 of FIG. 8B. Heat treatment is performed to respectively couple the metal core solder balls 38 to the first substrate pads 23.

Referring to FIG. 8D, the metal core solder balls 38 may be respectively formed on the first substrate pads 23 of the package substrate 20. The metal core solder balls 38 may be formed on the edge portion of the package substrate 20.

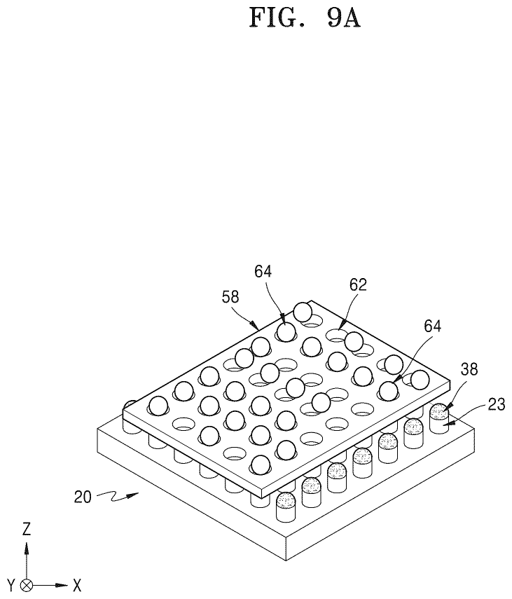

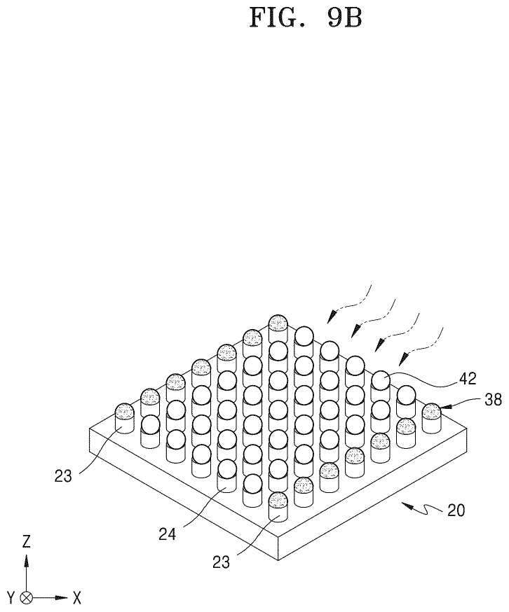

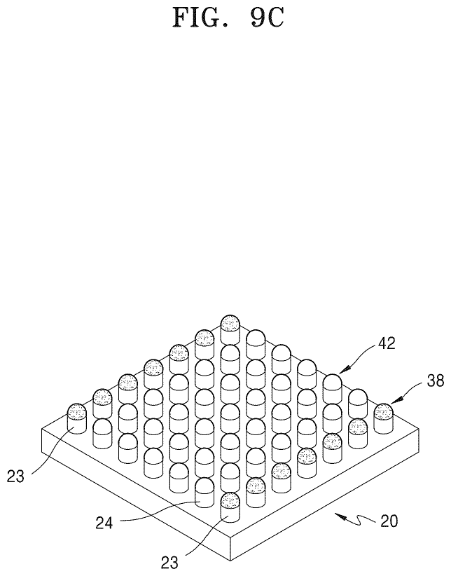

FIGS. 9A to 9C are perspective views illustrating a process of forming the core-free solder balls 42 on the second substrate pads 24 of the package substrate 20 of FIGS. 6 and 7.

As shown in FIG. 9A, a solder mask 58 having openings 62 is disposed on the package substrate 20 that is a result of FIG. 8D. The openings 62 in the solder mask 58 may be formed to correspond to the second substrate pads 24. The solder mask 58 is coated or applied with a core-free solder material 64.

Referring to FIG. 9B, the core-free solder balls 42 may be respectively formed on the second substrate pads 24 by passing the core-free solder material 64 through the openings 62 formed in the solder mask 58 of FIG. 9A.

The heights of the core-free solder balls 42 may differ from each other due to the differences in the diameters of the second substrate pads 24. The heights of the core-free solder balls 42 may be adjusted to vary according to the degree and direction of the warpage of the package substrate 20. Successively, heat treatment is performed to respectively couple the core-free solder balls 42 to the second substrate pads 24.

Referring to FIG. 9C, the core-free solder balls 42 may be respectively formed on the second substrate pads 24 of the package substrate 20. The core-free solder balls 42 may be formed on a center portion of the package substrate 20.

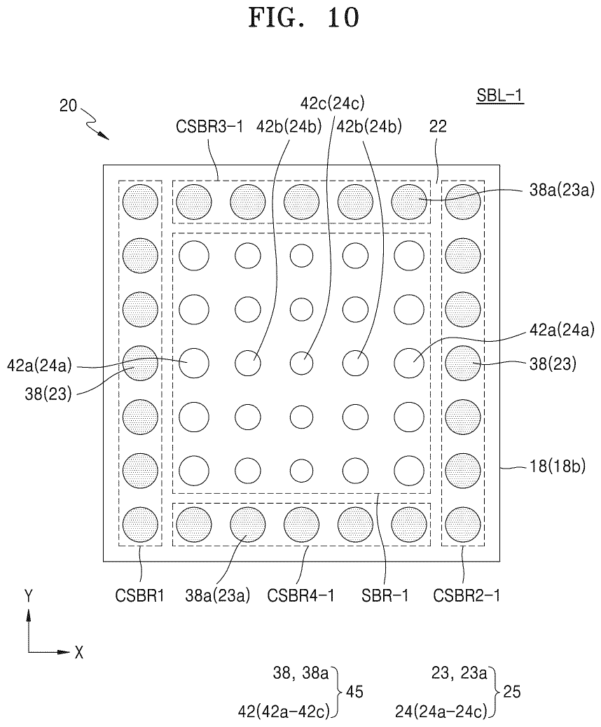

FIG. 10 is a planar layout diagram SBL-1 illustrating connection balls on substrate pads of a package substrate according to an embodiment.

Particularly, the planar layout diagram SBL-1 of FIG. 10 may be a different example from the planar layout diagram SBL of FIG. 6. The planar layout diagram SBL-1 of FIG. 10 may be the same as the planar layout diagram SBL of FIG. 6 except that metal core solder balls 38 and 38a are near the edges of the four sides of the quadrangular-shaped package substrate 20. In FIG. 10, like or similar reference numerals of FIGS. 1, 4, 6, and 7 denote like or similar members. In FIG. 10, the description made with reference to FIGS. 1, 4, 6, and 7 is simply repeated or omitted.

The planar layout diagram SBL-1 of FIG. 10 shows connection balls 45 on the lower surface 18b of the package body 18 constituting the package substrate 20. The package substrate 20, i.e., the package body 18, may have a quadrangular shape. The connection balls 45 may be respectively on substrate pads 25 on the lower surface 18b of the package body 18. The substrate protective layer 22 isolating the substrate pads 25 may be on the lower surface 18b of the package body 18.

The substrate pads 25 may include first substrate pads 23 and 23a and second substrate pads 24. The connection balls 45 may include metal core solder balls 38 and 38a and core-free solder balls 42. The metal core solder balls 38 and 38a may be respectively on the first substrate pads 23 and 23a. The core-free solder balls 42 may be respectively on the second substrate pads 24.

The metal core solder balls 38 and 38a may be on edge portions, e.g., first to fourth edge portions CSBR1-1, CSBR2-1, CSBR3-1, and CSBR4-1, of the package substrate 20, i.e., the package body 18. The metal core solder balls 38 and 38a may be on the first edge portion CSBR1-1, the second edge portion CSBR2-1, the third edge portion CSBR3-1, and the fourth edge portion CSBR4-1 near the edges of the four sides of the quadrangular-shaped package substrate 20.

In one or more embodiments, the metal core solder balls 38 and 38a may be on at least any one of the first edge portion CSBR1-1, the second edge portion CSBR2-1, the third edge portion CSBR3-1, and the fourth edge portion CSBR4-1. In one or more embodiments, the metal core solder balls 38 and 38a of FIG. 10 are all near the edges of the four sides of the package substrate 20 but may not be near a portion of the edges of the four sides of the package substrate 20.

The core-free solder balls 42 may be on a center portion SBR-1 of the package substrate 20, i.e., the package body 18. The core-free solder balls 42 may be at an inner side of the first to fourth edge portions CSBR1-1, CSBR2-1, CSBR3-1, and CSBR4-1 of the quadrangular-shaped package substrate 20.

The diameters of the second substrate pads 24, on which the core-free solder balls 42 are respectively disposed, may vary at the center portion SBR-1 of the package substrate 20. For example, the diameters of the second substrate pads 24, on which the core-free solder balls 42 are respectively disposed, may gradually decrease from the first to fourth edge portions CSBR1-1, CSBR2-1, CSBR3-1, and CSBR4-1 to the center portion SBR-1 of the package substrate 20. Because the diameters of the second substrate pads 24 are described above, a description thereof is omitted herein.

The heights of the core-free solder balls 42 respectively on the second substrate pads 24 may vary on the center portion SBR-1 of the package substrate 20. The heights of the core-free solder balls 42 respectively on the second substrate pads 24 may gradually increase from the first to fourth edge portions CSBR1-1, CSBR2-1, CSBR3-1, and CSBR4-1 to the center portion SBR-1 of the package substrate 20. Because the heights of the core-free solder balls 42 are described above, a description thereof is omitted herein.

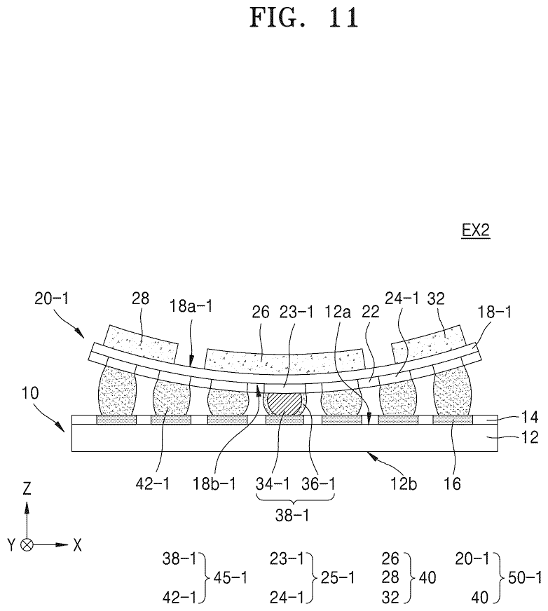

FIG. 11 is a cross-sectional view illustrating a board-level semiconductor package EX2 according to an embodiment.

Particularly, the board-level semiconductor package EX2 may be the same as the board-level semiconductor package EX1 of FIG. 1 except that a package substrate 20-1 has negative warpage protruding downward (e.g., may be concave downward), toward the board substrate 10.

The board-level semiconductor package EX2 may be the same as the board-level semiconductor package EX1 of FIG. 1 except for the arrangement and sizes of a first substrate pad 23-1 and second substrate pads 24-1 formed on the package substrate 20-1. In FIG. 11, like or similar reference numerals of FIG. 1 denote like or similar members. In FIG. 11, the same or similar description as or to that made with reference to FIG. 1 is simply repeated or omitted.

The board-level semiconductor package EX2 may include the board substrate 10, a modular semiconductor package 50-1 including the package substrate 20-1 and semiconductor packages 40, and connection balls 45-1. The board substrate 10 may include the board body 12 having the upper surface 12a and the lower surface 12b, the plurality of board pads 16, and the board protective layer 14. The board substrate 10 may indicate the board body 12 in a narrow meaning.

The package substrate 20-1 may include a package body 18-1 having an upper surface 18a-1 and a lower surface 18b-1, a plurality of substrate pads 25-1 on the lower surface 18b-1 of the package body 18-1 and separated from each other, and the substrate protective layer 22 isolating the plurality of substrate pads 25-1. The package substrate 20-1 may indicate the package body 18-1 in a narrow meaning.

The package substrate 20-1 may have warped during a manufacturing process thereof. In one or more embodiments, the package substrate 20-1, i.e., the package body 18-1, may have negative warpage protruding downward (e.g., may be concave downward), toward the board substrate 10.

The semiconductor packages 40 are on the upper surface 18a-1 of the package substrate 20-1, i.e., the package body 18-1, and separated from each other. The semiconductor packages 40 may include the first semiconductor package 26, the second semiconductor package 28, and the third semiconductor package 32 in a cross-sectional view.

A structure including the package substrate 20-1 and the semiconductor packages 40 on the package substrate 20-1 may be referred to as the modular semiconductor package 50-1. In the present embodiment, the semiconductor packages 40 are on the package substrate 20-1, but semiconductor chips may be on the package substrate 20-1.

The connection balls 45-1 may be between the board substrate 10 and the package substrate 20-1 and may respectively electrically connect the plurality of board pads 16 to the plurality of substrate pads 25-1. The connection balls 45-1 may include a metal core solder ball 38-1 and a plurality of core-free solder balls 42-1. The metal core solder ball 38-1 may include a metal core 34-1 and a core solder layer 36-1 wrapping the metal core 34-1.

The plurality of core-free solder ball 42-1 may indicate solder balls without a metal core. The plurality of core-free solder balls 42-1 may include the same material as the core solder layer 36-1. The metal core solder ball 38-1 and the plurality of core-free solder balls 42-1 may be on the plurality of substrate pads 25-1 and electrically connect the plurality of board pads 16 to the plurality of substrate pads 25-1, respectively.

The plurality of substrate pads 25-1 may be classified into the first substrate pad 23-1, on which the metal core solder ball 38 is disposed, and the second substrate pads 24-1, on which the plurality of core-free solder balls 42-1 are respectively disposed. As described above, the package substrate 20-1 may have warpage in a manufacturing process thereof. For example, as described above, the package substrate 20-1, i.e., the package body 18-1, may have negative warpage protruding downward (e.g., may be concave downward), toward the board substrate 10. Accordingly, the metal core solder ball 38 is on a center portion of the package substrate 20-1.

In addition, the diameters of the second substrate pads 24-1, on which the plurality of core-free solder balls 42-1 are respectively disposed, gradually decrease from the center portion to an edge portion of the package substrate 20-1. In one or more embodiments, the diameter of each of the second substrate pads 24-1, on which the plurality of core-free solder balls 42-1 are respectively disposed, may be about 50% to about 100% of the diameter of the first substrate pad 23-1, on which the metal core solder ball 38-1 is disposed. The heights of the plurality of core-free solder balls 42-1 respectively on the second substrate pads 24-1 may gradually increase from the center portion to the edge portion of the package substrate 20-1.

The board-level semiconductor package EX2 according to the disclosure may be configured such that the diameters of the second substrate pads 24-1, on which the plurality of core-free solder balls 42-1 are respectively disposed, vary according to the degree and direction of the warpage of the package substrate 20-1. In addition, the heights of the plurality of core-free solder balls 42-1 respectively on the second substrate pads 24-1 may vary according to the degree and direction of the warpage of the package substrate 20-1.

In addition, the board-level semiconductor package EX2 according to the disclosure may include the board substrate 10 and the package substrate 20-1 electrically connected to each other using the metal core solder ball 38-1 and the plurality of core-free solder balls 42-1 and have improved package flatness. In other words, in the board-level semiconductor package EX2 according to the disclosure, the package flatness of the board substrate 10 and the package substrate 20-1 may be improved using the metal core solder ball 38-1, and the board substrate 10 may be electrically connected to the package substrate 20-1 by using the plurality of core-free solder balls 42-1.

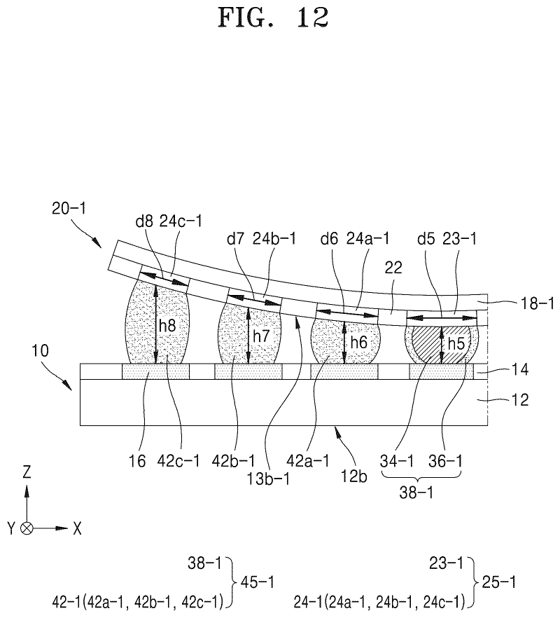

FIG. 12 is a partial magnified cross-sectional view of the board-level semiconductor package EX2 of FIG. 11.

Particularly, in FIG. 12, like reference numerals of FIG. 11 denote like members. In FIG. 12, the description made with reference to FIG. 11 is simply repeated or omitted. The board-level semiconductor package EX2 may include the board substrate 10, the package substrate 20-1, and connection balls 45-1.

The board substrate 10 may include the board body 12 having the upper surface 12a and the lower surface 12b, board pads 16, and the board protective layer 14. The package substrate 20-1 may include the package body 18-1 having the upper surface 18a and the lower surface 18b, substrate pads 25-1, and the substrate protective layer 22. The connection balls 45-1 may be respectively on the substrate pads 25-1 on the lower surface 18b of the package body 18-1.

The connection balls 45-1 may include a metal core solder ball 38-1 and core-free solder balls 42-1. The heights of the core-free solder balls 42-1 respectively on second substrate pads 24-1 may differ on an edge portion of the package substrate 20-1. The core-free solder balls 42-1 may include a first sub-core-free solder ball 42a-1, a second sub-core-free solder ball 42b-1, and a third sub-core-free solder ball 42c-1.

The first sub-core-free solder ball 42a-1, the second sub-core-free solder ball 42b-1, and the third sub-core-free solder ball 42c-1 may have heights of h6, h7, and h8, respectively. The metal core solder ball 38-1 may have a height of h5. In one or more embodiments, the height h1 of the metal core solder ball 38-1 may be several um to hundreds of μm.

The substrate pads 25-1 may include the first substrate pad 23-1, on which the metal core solder ball 38-1 is disposed, and the second substrate pads 24-1, on which the core-free solder balls 42-1 are respectively disposed. The diameter of the first substrate pad 23-1 may be d5. The diameters of the second substrate pads 24-1 may be d6, d7, and d8. In one or more embodiments, each of the diameters d6, d7, and d8 of the second substrate pads 24-1 may be about 50% to about 100% of the diameter d5 of the first substrate pad 23-1.

The second substrate pads 24-1 may include a first sub-substrate pad 24a-1, a second sub-substrate pad 24b-1, and a third sub-substrate pad 24c-1. The first sub-substrate pad 24a-1, the second sub-substrate pad 24b-1, and the third sub-substrate pad 24c-1 may have diameters of d6, d7, and d8, respectively.

The metal core solder ball 38-1 may connect a board pad 16 to the first substrate pad 23-1. The first sub-core-free solder ball 42a-1 may connect a board pad 16 to the first sub-substrate pad 24a-1. The second sub-core-free solder ball 42b-1 may connect a board pad 16 to the second sub-substrate pad 24b-1. The third sub-core-free solder ball 42c-1 may connect a board pad 16 to the third sub-substrate pad 24c-1.

As described above, the package substrate 20-1 of the board-level semiconductor package EX2 may have negative warpage protruding downward (e.g., may be concave downward), toward the board substrate 10. The gap between a center portion of the package substrate 20-1 and a center portion of the board substrate 10 may be small and the gap between the edge portion of the package substrate 20-1 and an edge portion of the board substrate 10 may be large.

Accordingly, the diameters of the second substrate pads 24-1, on which the core-free solder balls 42-1 are respectively disposed, may gradually decrease from the center portion to the edge portion of the package substrate 20-1. The diameters of the first sub-substrate pad 24a-1, the second sub-substrate pad 24b-1, and the third sub-substrate pad 24c-1 may decrease in the order of d6, d7, and d8. In one or more embodiments, the diameter d5 of the first substrate pad 23-1 may be greater than the diameter d6 of the first sub-substrate pad 24a-1.

In addition, the heights of the core-free solder balls 42-1 respectively on the second substrate pads 24-1 may gradually increase from the center portion to the edge portion of the package substrate 20-1. That is, the heights of the first sub-core-free solder ball 42a-1, the second sub-core-free solder ball 42b-1, and the third sub-core-free solder ball 42c-1 may increase in the order of h6, h7, and h8.

In one or more embodiments, the heights h6, h7, and h8 of the core-free solder balls 42-1, i.e., the first to third sub-core-free solder balls 42a-1, 42b-1, and 42c-1, may be several μm to hundreds of μm. In one or more embodiments, the height h5 of the metal core solder ball 38-1 may be less than the height h6 of the first sub-core-free solder ball 42a-1.

Accordingly, the package substrate 20-1 may be connected to the board substrate 10 by using the metal core solder ball 38-1 even when the gap between the package substrate 20-1 and the board substrate 10 is small at the center portion of the package substrate 20-1. In addition, the package substrate 20-1 may be connected to the board substrate 10 by using the first to third sub-core-free solder balls 42a-1, 42b-1, and 42c-1 even when the gap between the package substrate 20-1 and the board substrate 10 is large at the edge portion of the package substrate 20-1.

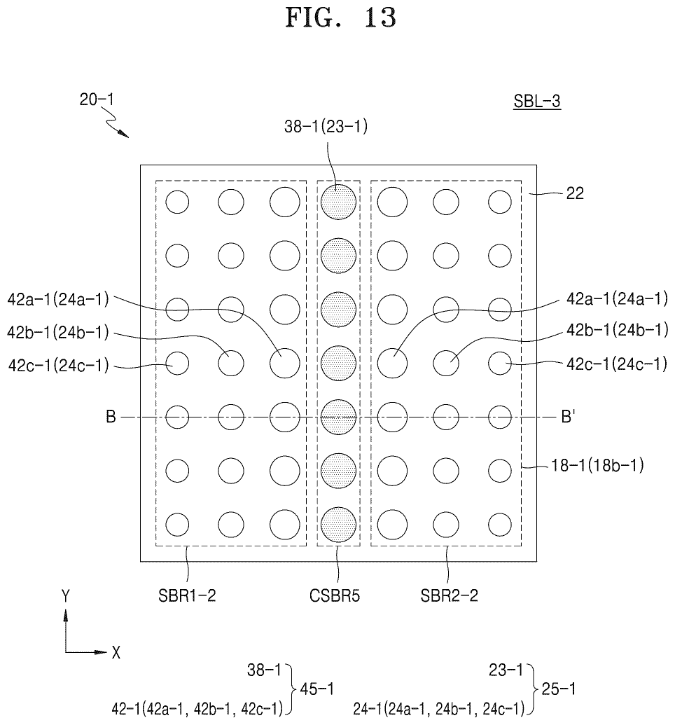

FIG. 13 is a planar layout diagram SBL-3 illustrating connection balls on substrate pads of the package substrate 20-1 of FIGS. 11 and 12, and FIG. 14 is a partial magnified planar layout diagram of FIG. 13.

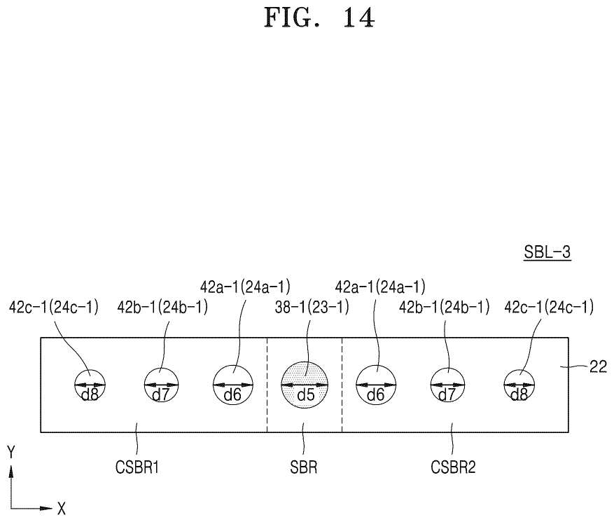

Particularly, in FIGS. 13 and 14, like reference numerals of FIGS. 11 and 12 denote like members. In FIGS. 13 and 14, the description made with reference to FIGS. 11 and 12 is simply repeated or omitted. The planar layout diagram SBL-3 of FIG. 13 shows connection balls 45-1 on the lower surface 18b-1 of the package body 18-1 constituting the package substrate 20-1. FIG. 14 may be a cross-sectional view taken along line B-B′ of FIG. 13.

The package substrate 20-1, i.e., the package body 18-1, may have a quadrangular shape. The connection balls 45-1 may be respectively on substrate pads 25-1 on the lower surface 18b-1 of the package body 18-1. The substrate protective layer 22 isolating the substrate pads 25-1 may be on the lower surface 18b-1 of the package body 18-1.

The substrate pads 25-1 may include first substrate pads 23-1 and second substrate pads 24-1. The connection balls 45-1 may include metal core solder balls 38-1 and core-free solder balls 42-1. The metal core solder balls 38-1 may be respectively on the first substrate pads 23-1. The core-free solder balls 42-1 may be respectively on the second substrate pads 24-1.

The metal core solder balls 38-1 may be on a center portion CSBR5 of the package substrate 20-1, i.e., the package body 18-1. The core-free solder balls 42-1 may be on edge portions, e.g., first and second edge portions SBR1-2 and SBR2-2, of the package substrate 20-1, i.e., the package body 18-1. The core-free solder balls 42-1 may be at an inner side of the first edge portion SBR1-2 and the second edge portion SBR2-2 of the quadrangular-shaped package substrate 20-1.

The diameters of the second substrate pads 24-1, on which the core-free solder balls 42-1 are respectively disposed, may vary on the first and second edge portions SBR1-2 and SBR2-2 of the package substrate 20-1. For example, the diameters of the second substrate pads 24-1, on which the core-free solder balls 42-1 are respectively disposed, may gradually decrease from the center portion CSBR5 to the first and second edge portions SBR1-2 and SBR2-2 of the package substrate 20-1.

The diameters of the first sub-substrate pad 24a-1, the second sub-substrate pad 24b-1, and the third sub-substrate pad 24c-1 constituting the second substrate pads 24 may decrease in the order of d6, d7, and d8.

In one or more embodiments, the diameter d5 of the first substrate pad 23-1 may be several um to hundreds of um. In one or more embodiments, the diameters d6, d7, and d8 of the first sub-substrate pad 24a-1, the second sub-substrate pad 24b-1, and the third sub-substrate pad 24c-1 constituting the second substrate pads 24-1 may be several μm to hundreds of μm. In one or more embodiments, the diameter d5 of the first substrate pad 23-1 may be greater than the diameter d6 of the first sub-substrate pad 24a-1.

As described above, the heights of the core-free solder balls 42-1 respectively on second substrate pads 24-1 may differ at the first and second edge portions SBR1-2 and SBR2-2 of the package substrate 20-1. The heights of the core-free solder balls 42-1 respectively on the second substrate pads 24-1 may gradually increase from the center portion CSBR5 to the first and second edge portions SBR1-2 and SBR2-2 of the package substrate 20-1.

For example, as described above, the heights of the first sub-core-free solder ball 42a-1, the second sub-core-free solder ball 42b-1, and the third sub-core-free solder ball 42c-1 may increase in the order of h6, h7, and h8. In one or more embodiments, the height h5 of the metal core solder ball 38-1 may be less than the height h6 of the first sub-core-free solder ball 42a-1.

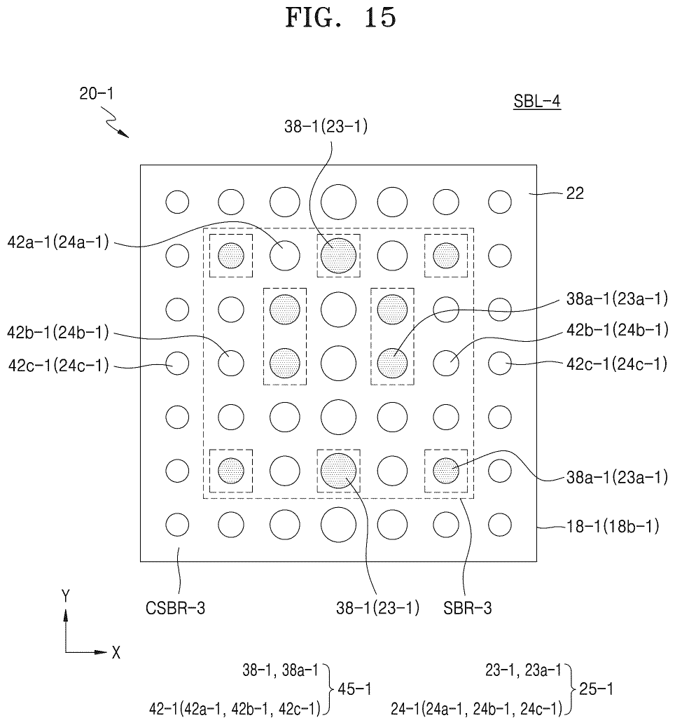

FIG. 15 is a planar layout diagram SBL-4 illustrating connection balls on substrate pads of a package substrate according to an embodiment.

Particularly, the planar layout diagram SBL-4 may be the same as the planar layout diagram SBL-3 of FIG. 13 except that metal core solder balls 38-1 and 38a-1 are freely distributed on the lower surface 18b-1 of the package substrate 20-1. In FIG. 15, like or similar reference numerals of FIGS. 10 to 14 denote like or similar members. In FIG. 15, the description made with reference to FIGS. 10 to 14 is simply repeated or omitted.

The package substrate 20-1, i.e., the package body 18-1, may have a quadrangular shape. Connection balls 45-1 may be respectively on substrate pads 25-1 on the lower surface 18b-1 of the package body 18-1. The substrate protective layer 22 isolating the substrate pads 25-1 may be on the lower surface 18b-1 of the package body 18-1.

The substrate pads 25-1 may include first substrate pads 23-1 and 23a-1 and second substrate pads 24-1. The connection balls 45-1 may include the metal core solder balls 38-1 and 38a-1 and core-free solder balls 42-1. The metal core solder balls 38-1 and 38a-1 may be respectively on the first substrate pads 23-1 and 23a-1. The core-free solder balls 42-1 may be respectively on the second substrate pads 24-1.

The metal core solder balls 38-1 and 38a-1 may be freely disposed on a center portion SBR-3 or an edge portion CSBR-3 of the package substrate 20-1, i.e., the package body 18-1. The core-free solder balls 42-1 may also be freely disposed on the center portion SBR-3 or the edge portion CSBR-3 of the package substrate 20-1, i.e., the package body 18-1.

In one or more embodiments, the substrate pads 25-1 may include the first substrate pads 23-1 and 23a-1, on which the metal core solder balls 38-1 and 38a-1 are respectively disposed, and the second substrate pads 24-1, on which the core-free solder balls 42-1 are respectively disposed. Metal core solder balls 38-1 and 38a-1 respectively on single first substrate pads 23-1 and 23a-1 may be on the center portion SBR-3 of the package body 18-1.

Metal core solder balls 38a-1 respectively on dual first substrate pads 23a-1 may be on the center portion SBR-3 of the package body 18-1. In one or more embodiments, unlike FIG. 15, metal core solder balls may be on the edge portion CSBR-3 of the package body 18-1.

In one or more embodiments, the second substrate pads 24-1 may be on the center portion SBR-3 or the edge portion CSBR-3 of the package body 18-1. The second substrate pads 24-1 may include a first sub-substrate pad 24a-1, a second sub-substrate pad 24b-1, and a third sub-substrate pad 24c-1.

The diameters of the first sub-substrate pad 24a-1, the second sub-substrate pad 24b-1, and the third sub-substrate pad 24c-1 may decrease in their order. In one or more embodiments, the diameter of the first substrate pad 23-1 may be greater than the diameter of the first sub-substrate pad 24a-1.

The core-free solder balls 42-1 may include a first sub-core-free solder ball 42a-1, a second sub-core-free solder ball 42b-1, and a third sub-core-free solder ball 42c-1. The heights of the first sub-core-free solder ball 42a-1, the second sub-core-free solder ball 42b-1, and the third sub-core-free solder ball 42c-1 may increase in their order as described above. In one or more embodiments, the heights of the metal core solder balls 38-1 and 38a-1 may be less than the height of the first sub-core-free solder ball 42a-1.

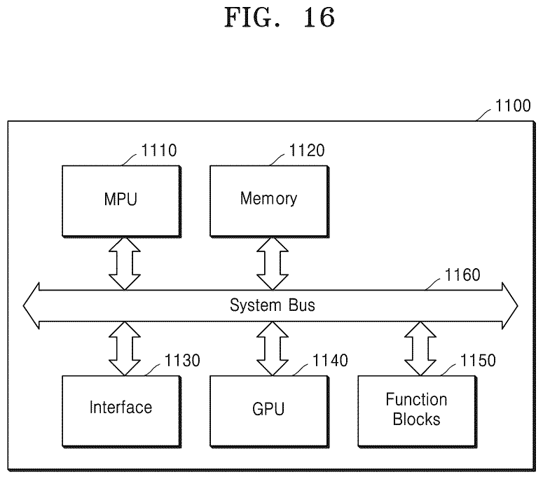

FIG. 16 is a block diagram schematically illustrating a board-level semiconductor package 1100 according to an embodiment.

Particularly, the board-level semiconductor package 1100 may include a microprocessor unit 1110, a memory 1120, an interface 1130, a graphics processing unit 1140, function blocks 1150, and a bus 1160 connecting the same to each other. The board-level semiconductor package 1100 may include one or both of the microprocessor unit 1110 and the graphics processing unit 1140.

The microprocessor unit 1110 may include a core and an L2 cache. For example, the microprocessor unit 1110 may include multiple cores. The multiple cores may have the same or different functions. In addition, the multiple cores may be activated at the same time or different time points. The memory 1120 may store results processed by the function blocks 1150, under control by the microprocessor unit 1110. For example, the contents stored in the L2 cache of the microprocessor unit 1110 may flush and be stored in the memory 1120. The interface 1130 may interface with external devices. For example, the interface 1130 may interface with a camera, a liquid crystal display (LCD), a speaker, and the like.

The graphics processing unit 1140 may perform graphics functions. For example, the graphics processing unit 1140 may perform a video codec function or process three-dimensional (3D) graphics. The function blocks 1150 may perform various functions. For example, when the board-level semiconductor package 1100 is an application processor (AP) used for a mobile device, some of the function blocks 1150 may perform a communication function.

The board-level semiconductor package 1100 may include any one of the board-level semiconductor packages EX1 and EX2 described above. The microprocessor unit 1110 and/or the graphics processing unit 1140 may include any one of the board-level semiconductor packages EX1 and EX2 described above. The memory 1120 may include any one of the board-level semiconductor packages EX1 and EX2 described above. The interface 1130 and the function blocks 1150 may include any one of the board-level semiconductor packages EX1 and EX2 described above.

While the disclosure has been particularly shown and described with reference to embodiments thereof, it will be understood that various changes in form and details may be made therein without departing from the spirit and scope of the following claims.

What is claimed is:

1. A semiconductor package comprising:
a package substrate comprising a plurality of substrate pads, wherein the plurality of substrate pads are separate from one another; and
a plurality of connection balls on the plurality of substrate pads,
wherein the plurality of connection balls comprise:
a plurality of metal core solder balls; and
a plurality of core-free solder balls,
wherein the plurality of substrate pads comprise first substrate pads and second substrate pads,
wherein the plurality of metal core solder balls are on the first substrate pads, and the plurality of core-free solder balls are on the second substrate pads, and
wherein a diameter of a first substrate pad among the second substrate pads is different a diameter of a second substrate pad from among the second substrate pads.

2. The semiconductor package of claim 1, further comprising a plurality of board pads,
wherein the plurality of board pads are on a board substrate and are separate from one another,
wherein the plurality of substrate pads respectively face the plurality of board pads,
wherein the plurality of connection balls are between the plurality of board pads and the package substrate, and
wherein the plurality of connection balls connect the plurality of board pads to the plurality of substrate pads.

3. The semiconductor package of claim 1,
wherein the package substrate is warped, and
wherein heights of the plurality of core-free solder balls vary according to the warpage of the package substrate.

4. The semiconductor package of claim 1,
wherein the package substrate is warped, and
wherein diameters of the second substrate pads vary according to the warpage of the package substrate.

5. The semiconductor package of claim 1, wherein a diameter of each of the second substrate pads is about 50% to about 100% of a diameter of each of the first substrate pads.

6. The semiconductor package of claim 1,
wherein the package substrate comprises a package body comprising an upper surface and a lower surface opposite to the upper surface,
wherein the plurality of substrate pads are on the lower surface of the package body, and
wherein a substrate protective layer is on the lower surface of the package body and isolates the plurality of substrate pads.

7. The semiconductor package of claim 2, wherein the package substrate has positive warpage protruding upward away from the board substrate or negative warpage protruding downward toward the board substrate.

8. The semiconductor package of claim 1,
wherein the package substrate has a quadrangular shape, and the plurality of metal core solder balls are on an edge portion of the package substrate, and
wherein the plurality of metal core solder balls are arranged along either two sides or four sides of the package substrate.

9. The semiconductor package of claim 1,
wherein the package substrate has a quadrangular shape, and
wherein the plurality of metal core solder balls are on a center portion of the package substrate.

10. The semiconductor package of claim 1,
wherein the package substrate has a quadrangular shape, and
wherein the plurality of metal core solder balls are on at least one of a center portion of the package substrate and an edge portion of the package substrate.

11. A semiconductor package comprising:
a package substrate comprising a plurality of substrate pads, wherein the plurality of substrate pads are separate from one another; and
a plurality of connection balls on the plurality of substrate pads,
wherein the plurality of connection balls comprise:
a plurality of metal core solder balls; and
a plurality of core-free solder balls,
wherein the plurality of substrate pads comprise first substrate pads and second substrate pads,
wherein the plurality of metal core solder balls are on the first substrate pads, and the plurality of core-free solder balls are one the second substrate pads,
wherein the first substrate pads and the plurality of metal core solder balls are on an edge portion of the package substrate, and
wherein diameters of the second substrate pads decrease from the edge portion to a center portion of the package substrate.

12. The semiconductor package of claim 11, further comprising a plurality of board pads,
wherein the plurality of board pads are on a board substrate and are separate from one another,
wherein the plurality of substrate pads respectively face the plurality of board pads,
wherein the plurality of connection balls are between the plurality of board pads and the package substrate, and
wherein the plurality of connection balls connect the plurality of board pads to the plurality of substrate pads.

13. The semiconductor package of claim 11, wherein heights of the plurality of core-free solder balls increase from the edge portion to the center portion of the package substrate.

14. The semiconductor package of claim 12,
wherein the package substrate has positive warpage protruding upward away from the board substrate, and
wherein a diameter of each of the second substrate pads is about 50% to about 100% of a diameter of each of the first substrate pads.

15. The semiconductor package of claim 11,
wherein the package substrate comprises a package body comprising an upper surface and a lower surface opposite to the upper surface,
wherein the plurality of substrate pads are on the lower surface of the package body, and
wherein a substrate protective layer is on the lower surface of the package body and isolates the plurality of substrate pads.

16. The semiconductor package of claim 11,
wherein the package substrate has a quadrangular shape, and the plurality of metal core solder balls are on the edge portion of the package substrate, and
wherein the plurality of metal core solder balls are arranged along either two sides or four sides of the package substrate.

17. A semiconductor package comprising:
a package substrate comprising a plurality of substrate pads, wherein the plurality of substrate pads are separate from one another; and
a plurality of connection balls on the plurality of substrate pads,
wherein the plurality of connection balls comprise:
a plurality of metal core solder balls; and
a plurality of core-free solder balls,
wherein the plurality of substrate pads comprise first substrate pads and second substrate pads,
wherein the plurality of metal core solder balls are on the first substrate pads, and the plurality of core-free solder balls are on the second substrate pads,
wherein the first substrate pads and the plurality of metal core solder balls are on a center portion of the package substrate, and
wherein diameters of the second substrate pads decrease from the center portion to an edge portion of the package substrate.

18. The semiconductor package of claim 17, further comprising a plurality of board pads,
wherein the plurality of board pads are on a board substrate and are separate from one another,
wherein the plurality of substrate pads respectively face the plurality of board pads,
wherein the plurality of connection balls are between the plurality of board pads and the package substrate, and
wherein the plurality of connection balls connect the plurality of board pads to the plurality of substrate pads.

19. The semiconductor package of claim 18,
wherein the package substrate has negative warpage protruding downward toward the board substrate, and
wherein heights of the plurality of core-free solder balls increase from the center portion to the edge portion of the package substrate.

20. The semiconductor package of claim 17,
wherein the package substrate has a quadrangular shape, and
wherein the plurality of metal core solder balls are on the center portion of the package substrate.
